(19) United States
(12) Patent Application Publication
(10) Pub. No.: US 2012/0210936 A1
(43) Pub. Date: Aug. 23, 2012

(54) SYSTEMS AND METHODS FOR MUTLI-CHAMBER PHOTOVOLTAIC MODULE PROCESSING

(75) Inventors: Jerry Y. Wong, Saratoga, CA (US); Linh Xuong Can, San Jose, CA (US); Shichung Chu, Fremont, CA (US); Grant N. Wang, Us, CA (US); Hi V. Lam, Fremont, CA (US); Amar Singh, Fremont, CA (US); James Y. Liu, Sunnyvale, CA (US)

(73) Assignee: Ji Fu Machinery & Equipment Inc., San Jose, CA (US)

(21) Appl. No.: 13/353,151

(22) Filed: Jan. 18, 2012

Related U.S. Application Data
(60) Provisional application No. 61/444,918, filed on Feb. 21, 2011.

(51) Int. Cl. H01L 31/18; F03B 11/02

(52) U.S. Cl. 118/719; 137/561 R

(57) ABSTRACT

A system includes input and output sets processing chambers. The processing chambers of each of the input set and the output set are fluidly coupled and linearly aligned with each other along corresponding input and output directions. The processing chambers process and move a device between the processing chambers along corresponding input and output directions. The processing chambers of the input set separately process the device when the device is located in each of the processing chambers of the input set. The processing chambers of the output set separately process the device when the device is located in each of the processing chambers of the output set.

### CROSS-REFERENCE TO RELATED APPLICATIONS

This application claims priority to U.S. Provisional Application Ser. No. 61/444,918, titled “Interconnected Multi-Chamber System Used For Manufacturing A Photovoltaic Module,” and filed on 21-Feb.-2011 (referred to herein as the “'918 Application”). The entire disclosure of the '918 Application is incorporated by reference,

### BACKGROUND

The manufacturing of photovoltaic modules or devices involves many processes, including, but not limited to, heating, cooling, etching, material deposition, doping, and the like. Generally, a final photovoltaic module may be obtained after the at least some of these processes are carried out during a manufacturing process.

Presently, some processing systems are single chamber batch processing systems in which a single chamber is dedicated to a single type of process such as plasma etching or chemical vapor deposition, and the like. These process-dedicated batch-type systems are designed to process single modules or groups of modules at a time. However, there can be many problem associated with batch-type systems, including process control. For example, it may be difficult to obtain good uniformity cross an entire batch of modules when compared to individual processing of modules.

Some known systems include several chambers connected to a common platform to allow a substrate of a module being processed to move from one chamber to another without breaking a vacuum or other low pressure atmosphere inside the chambers. The modules may be moved between these chambers after the processing in one chamber is complete. In order to reduce contamination of the modules and/or reduce the time required to reduce the pressure and/or increase the temperature inside the chambers, the chambers may be sealed from the external atmosphere. However, sealing the chambers together in a common platform may also mean that the number of chambers that are interconnected can be limited.

For example, some known systems include unlimited amount of chambers connecting in series. Other than the flexibility of floor space, the unlimited chambers can also have problem for thermal expansion. For example, if the chambers are too close together to provide a seal between the chambers, then the thermal expansion of the chambers may cause the chambers to abut and/or damage each other. On the other hand, if the chambers are too far from each other, then an adequate seal may not be able to be maintained. The total thermal expansion or displacement of the chambers toward each other may be additive when the chambers are aligned along a linear direction. As a result, the number of chambers that can be coupled together may be limited so as to prevent too much thermal expansion and/or a requirement that the chambers be so far apart that an adequate seal may not be maintained.

### BRIEF SUMMARY

In one embodiment, a system (e.g., a system for forming one or more semiconductor layers on a device) includes an input set and an output set of processing chambers. The processing chambers of the input set are configured to be fluidly coupled and linearly aligned with each other along an input direction. The processing chambers of the input set are configured to process and move a device between the processing chambers of the input set along the input direction with the processing chambers of the input set separately processing the device when the device is located in each of the processing chambers of the input set. The processing chambers of the output set are configured to be fluidly coupled and linearly aligned with each other along an output direction, the processing chambers of the output set configured to process and move the device between the processing chambers of the output set along the output direction with the processing chambers of the output set separately processing the device when the device is located in each of the processing chambers of the output set.

In one aspect, several lines or sets of the processing chambers may be disposed parallel and/or side-by-side to each other. The lines or sets of processing chambers may provide the same processing functions. For example, if a first linear set of processing chambers (e.g., the input set) deposits an n-doped semiconductor layer, an intrinsic semiconductor layer, and a p-doped semiconductor layer, a second linear set of processing chambers oriented parallel to the first linear set (e.g., the output set) also may deposit the same layers in the same order. Additionally, one or more control and/or supply components may be disposed in the space between the parallel or side-by-side sets of processing chambers so that the processing chambers that provide the same processing functions can share one or more common (e.g., the same) control and/or supply components. For example, processing chambers that provide the same functions or processing may share the same control computer or processor, the same control system, vacuum pumps, gas panels, or any other common function components in order to reduce the cost and complexity of the system. A control component may be a device, system, or apparatus (e.g., computer, processor, actuator, and the like) that controls and/or directs the operations of the processing functions. A supply component may be a device, system, or apparatus that provides or supplies materials, atmospheres, and the like, used to perform the processing functions. For example, supply components can include vacuum pumps that provide a low pressure atmosphere, gas supply pumps that supply gases for the deposition of layers on the modules, power sources that provide electric fields for deposition of the layers, heating elements that heat the inside of chambers, and the like.

In another embodiment, another system (e.g., a system for processing a module) includes a first processing circuit, a second processing circuit, and a transition chamber. The first processing circuit has a first input set of processing chambers configured to be fluidly coupled and linearly aligned with each other along a first input direction, first output set of the processing chambers configured to be fluidly coupled and linearly aligned with each other along a first output direction, and a first bridging chamber extending between the first input set of processing chambers and the first output set of processing chambers. The second processing circuit has a second input set of processing chambers configured to be fluidly coupled and linearly aligned with each other along a second input direction, a second output set of the processing chambers configured to be fluidly coupled and linearly aligned with each other along a second output direction, and a second bridging chamber extending between the second input set of processing chambers and the second output set of processing chambers. The transition chamber is configured to be fluidly coupled with the first processing circuit and the second processing circuit. The first processing circuit is configured to process and move a semiconductor-based device through the processing chambers of the first processing circuit along the first input direction, the first transfer direction, and the first output direction. The transition chamber is configured to move the device to the second processing circuit. The second processing circuit is configured to process and move the device through the processing chambers of the second processing circuit along the second input direction, the second transfer direction, and the second output direction to deposit one or more semiconductor layers on the device.

In another embodiment, a multi-chamber system includes a plurality of chambers linearly aligned with each other, wherein each chamber performs a different processing function or step in a manufacturing process of a photovoltaic module.

### BRIEF DESCRIPTION OF THE DRAWINGS

The drawings, in which like numerals represent similar parts, illustrate generally, by way of example, but not by way of limitation, various embodiments discussed in the present document:

FIG. 1 is a perspective view of one embodiment of a multi-chamber system from an operator side of the system;

FIG. 2 is a perspective view of one embodiment of a loading robot;

FIG. 3 is a perspective view of the multi-chamber system from a gas distribution side of the system;

FIG. 4 is a diagram of the multi-chamber system;

FIGS. 5 through 8 are circuit diagrams for the supply of various gases to the multi-chamber system;

FIG. 9 is a cross-sectional view of an example of a photovoltaic module;

FIG. 10 is a cross-sectional view of another embodiment of a multi-chamber system;

FIG. 11 is a cross-sectional view of a semiconductor layer in accordance with one embodiment;

FIG. 12 is a cross-sectional view of another embodiment of a multi-chamber system;

FIG. 13 is a top view of the system shown in FIG. 12;

FIG. 14 is a perspective view of a transition chamber shown in FIG. 12 in accordance with one embodiment;

FIG. 15 is a perspective view of a lift mechanism and a carrier shown in FIG. 10 in accordance with one embodiment; and

FIG. 16 is a flowchart of one embodiment of a method for processing a device, such as a photovoltaic or solar module.

### DETAILED DESCRIPTION

The foregoing summary, as well as the following detailed description of certain embodiments of the subject matter set forth herein, will be better understood when read in conjunction with the appended drawings. As used herein, an element or step recited in the singular and proceeded with the word “a” or “an” should be understood as not excluding plural of said elements or steps, unless such exclusion is explicitly stated. Furthermore, references to “one embodiment” are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

In the following detailed description, reference is made to the accompanying drawings which form a part hereof, and in which are shown by way of illustration specific embodiments in which the subject matter disclosed herein may be practiced. These embodiments, which are also referred to herein as “examples,” are described in sufficient detail to enable one of ordinary skill in the art to practice the subject matter disclosed herein. It is to be understood that the embodiments may be combined or that other embodiments may be utilized, and that structural, logical, and electrical variations may be made without departing from the scope of the subject matter disclosed herein. The following detailed description is, therefore, not to be taken in a limiting sense, and the scope of the subject matter disclosed herein is defined by the appended claims and their equivalents. In the description that follows, like numerals or reference designators will be used to refer to like parts or elements throughout. In this document, the terms “a” or “an” are used, as is common in patent documents, to include one or more than one. In this document, the term “or” is used to refer to a nonexclusive or, unless otherwise indicated.

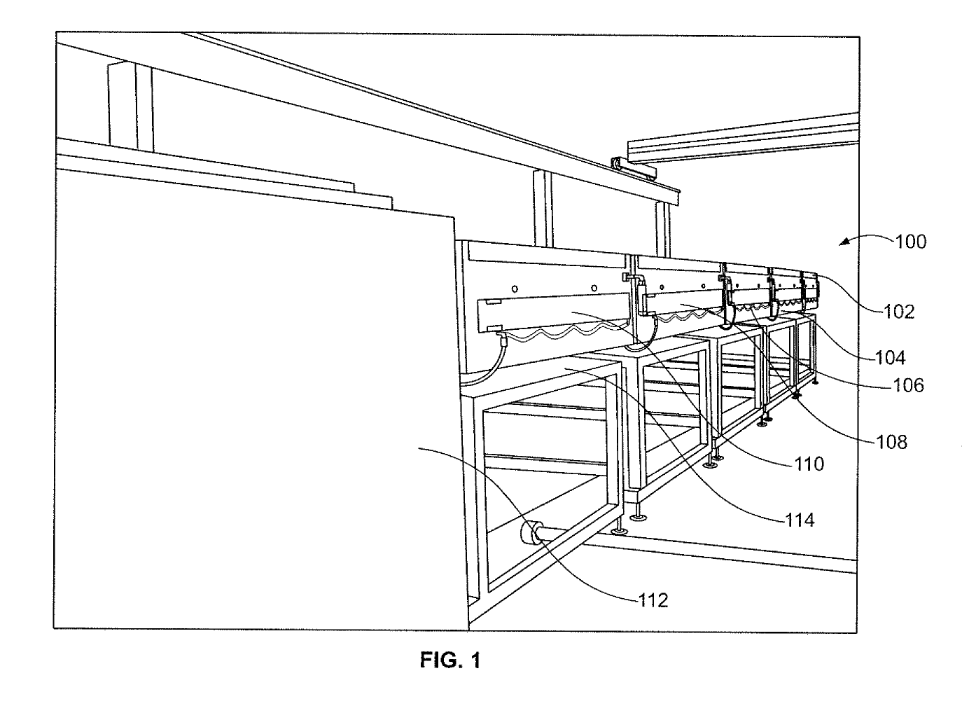

FIG. 1 is a perspective view of one embodiment of a multi-chamber system 100 from an operator side of the system 100. The system 100 is used to manufacture semiconductor devices such as photovoltaic devices (e.g., solar modules having 100 or more solar cells connected in series with each other). The system 100 includes several chambers 102, 104, 106, 108, 110, 112 linearly aligned with each other. The chambers 102, 104, 106, 108, 110, 112 are linearly aligned with each other such that a planar photovoltaic module or other substrate can linearly move between the chambers 102, 104, 106, 108, 110, 112.

FIG. 9 is a cross-sectional view of a solar module 900 that may be manufactured using the multi-chamber system 100. The solar module 900 includes several conductively coupled solar cells 918 that generate electric current from incident light. In the illustrated embodiment, the solar module 900 includes a substrate 902, a conductive lower electrode 904, a semiconductor layer 906, a conductive upper electrode 908, and a cover sheet 910. Several gaps 912 are cut through the lower electrode 904, several gaps 914 are cut through the semiconductor layer 906, and several gaps 916 are cut through the upper electrode 908 to define and separate the solar cells 918. Incident light is received through the cover sheet 910 or substrate 902 and received in the semiconductor layer 906. The semiconductor layer 906 converts the light into electric current that flows to the upper and lower electrodes 908, 906. This current is extracted from the module 900 and used for storage or to power an electric load.

Returning to the discussion of the multi-chamber system 100, each of the chambers 102, 104, 106, 108, 110, 112 may perform processing of a substrate to form a photovoltaic module. For example, one chamber may deposit the lower electrode 904, another chamber may deposit the semiconductor layer 906 (or one or more sub-layers or films of the semiconductor layer 906), another chamber may deposit the upper electrode 908, and one or more of the chambers may etch (e.g., laser etch) one or more of the gaps 912, 914, 916 in the lower electrode 904, the semiconductor layer 906, and/or the upper electrode 908.

A conveyor subsystem 114 may linearly move the module 900 between the chambers. By way of example, the conveyor subsystem 114 may include one or more conveyor belts upon which the module 900 rides through the chambers, one or more chains or belts that pull or push the module 900 (e.g., by attaching to the module 900 or a carrier on which the module 900 rides and moving the chain or belt to move the module 900 and carrier), and the like.

The chambers 102, 104, 106, 108, 110, 112 may be positioned such that the conveyor subsystem 114 sequentially moves the module 900 between the chambers for the various processing steps or operations. For example, the conveyor subsystem 114 may linearly move the module 900 from a first chamber that deposits the lower electrode 904 to a second, neighboring chamber that etches the gaps 912 in the lower electrode 904. The conveyor subsystem 114 may move the module 900 to other chambers to perform the remaining processing steps. In one embodiment, the conveyor subsystem 114 may switch directions to return the module 900 to a previously visited chamber to perform one or more processing steps.

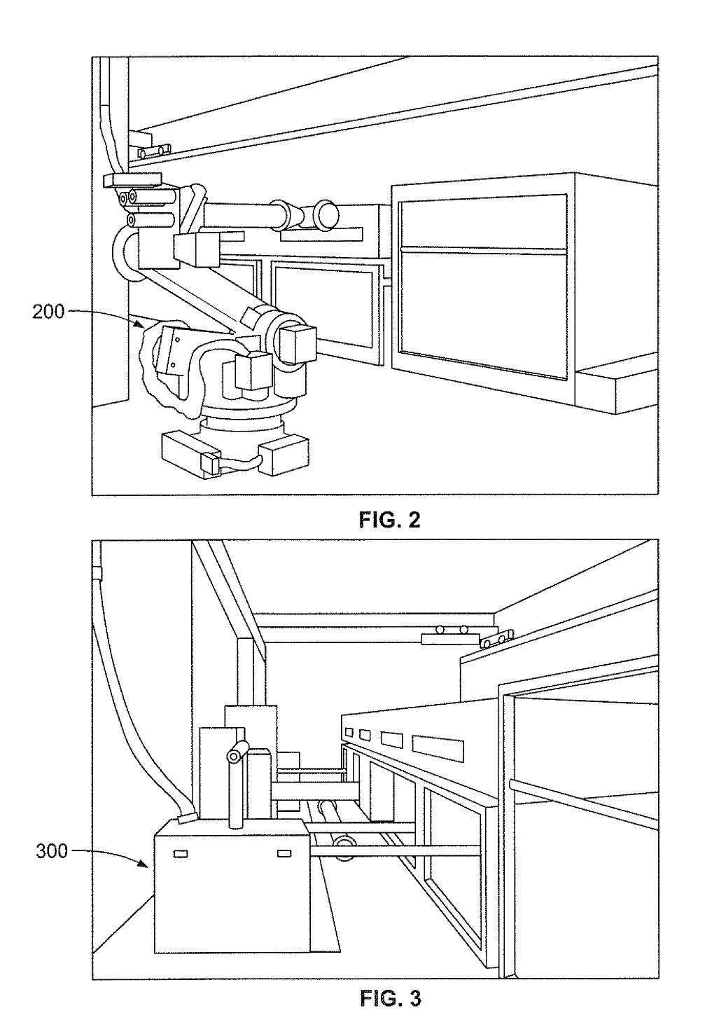

FIG. 2 is a perspective view of a loading robot assembly 200 in accordance with one embodiment. The robot assembly 200 can be configured to lift and/or lower the module 900 to a vertical position of one or more of the chambers. For example, the robot assembly 200 can lift the module 900 to a first processing chamber from a tower position.

FIG. 3 is a perspective view of the multi-chamber system 100 from a gas distribution side. FIG. 3 illustrates an opposite side of the system 100 relative to the side shown in FIG. 1. Several pumps, radio frequency (RF) generators, and/or sources of gas (generally referred to as 300) may be fluidly coupled with one or more of the chambers 102, 104, 106, 108, 110, 112. The pumps may lower the pressure in one or more chambers to a vacuum level, such as for the deposition of one or more of the tower electrode 904, the semiconductor layer 906, or the upper electrode 908 of the module 900. The RF generators may generate an RF field within one or more of the chambers. For example, an RF generator may create an RF field for plasma enhanced chemical vapor deposition (PECVD) of the semiconductor layer 906. The sources of gas may supply deposition gases used in the deposition of one or more layers, such as the semiconductor layer 906.

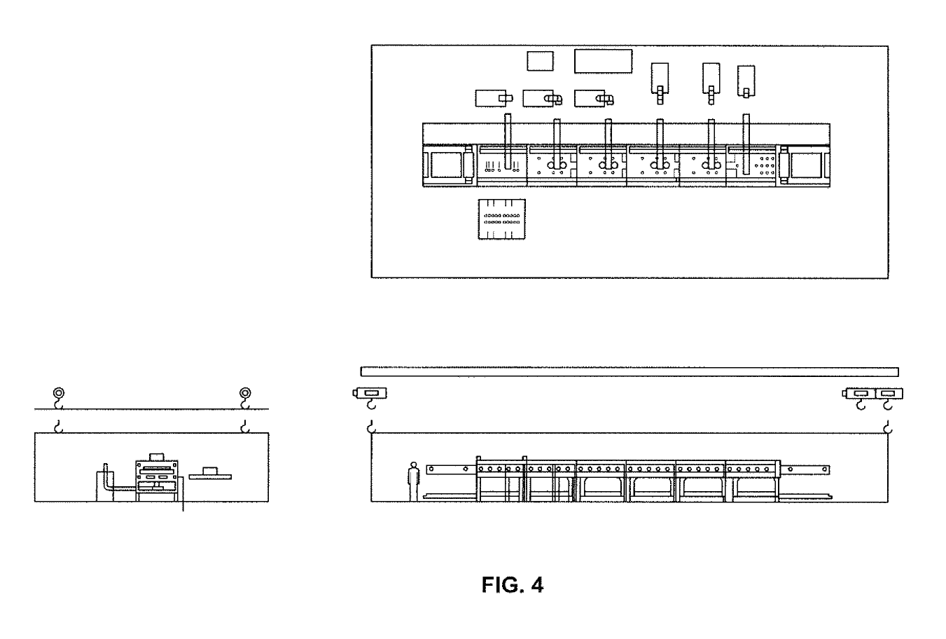

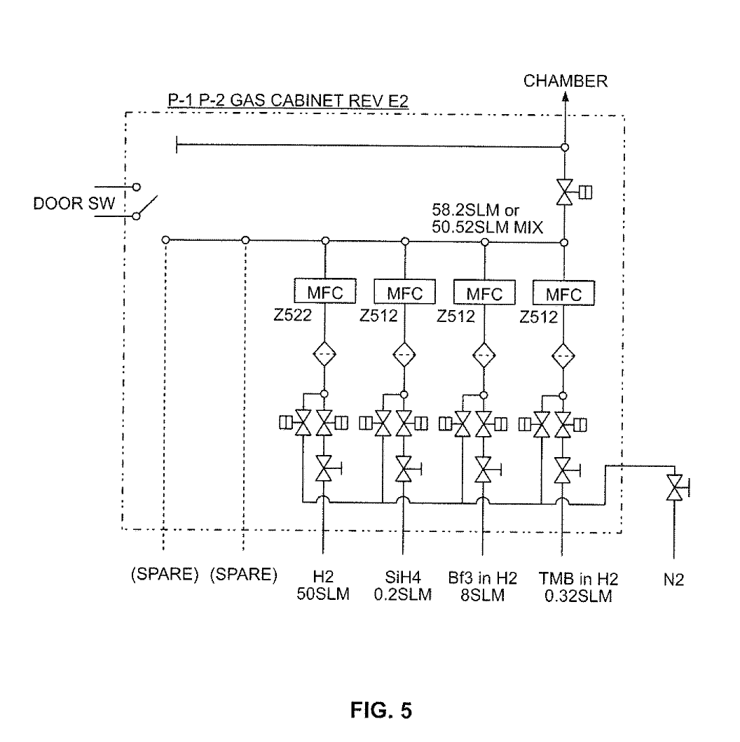

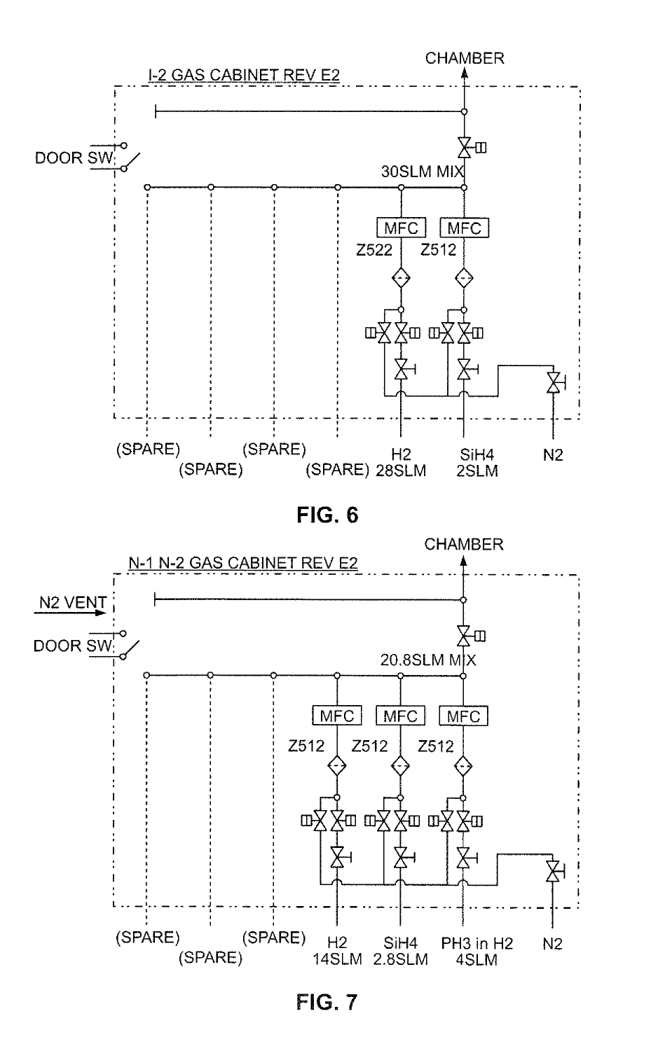

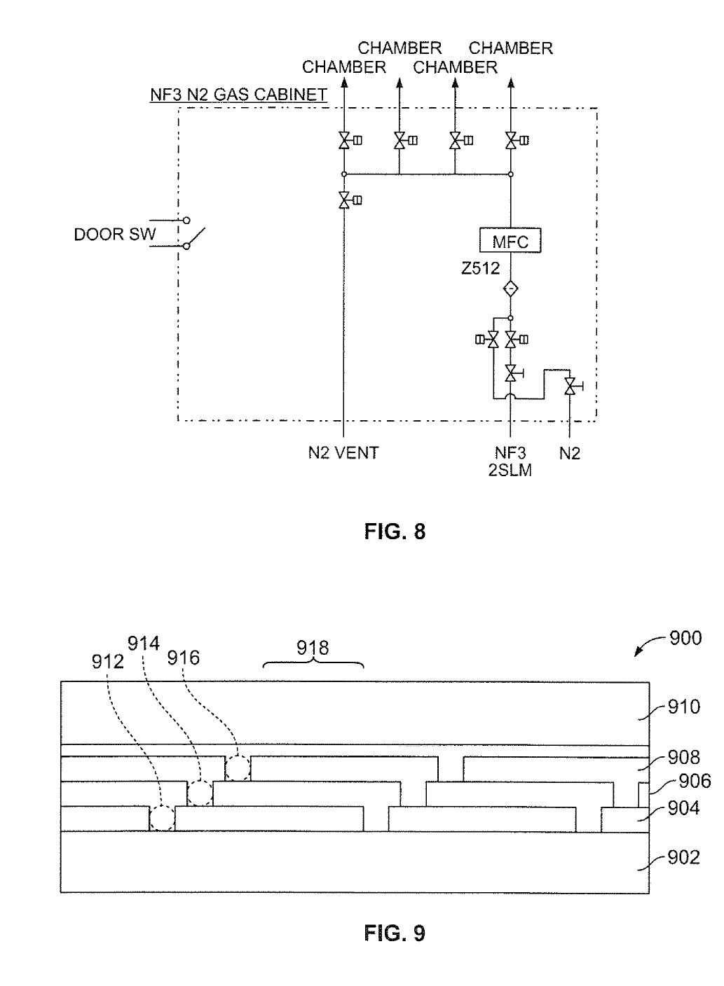

FIG. 4 provides top, side, and end views of the multi-chamber system 100. FIGS. 5 through 8 provide circuit diagrams that illustrate the flow paths of various gases into one or more chambers of the multi-chamber system 100. As shown in FIGS. 5 through 8, a single source of a gas may supply gas to several chambers.

While six chambers are shown in the illustrated embodiment, alternatively, a different number of chambers may be provided. The chambers may be capable of being closed of from one another. For example, once the module 900 is positioned in a chamber, the chamber may close itself such that air cannot enter into the chamber and deposition gases cannot exit the chamber.

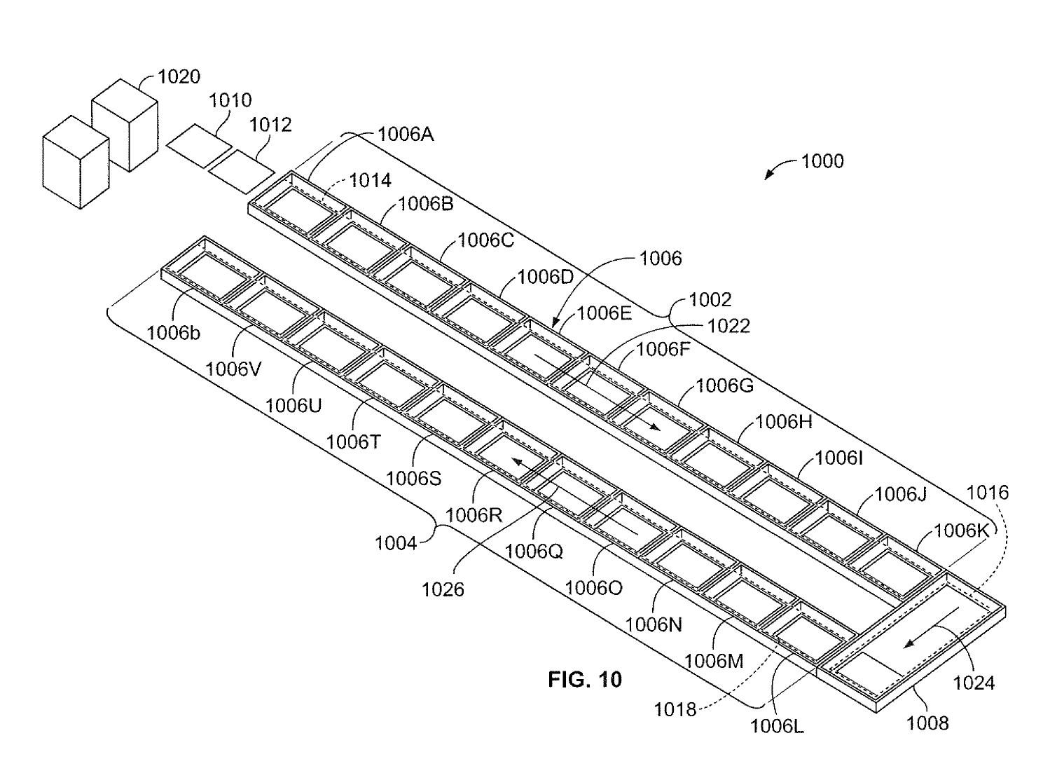

FIG. 10 is a cross-sectional view of another embodiment of a multi-chamber system 1000. The view shown in FIG. 10 presents the bottom half of the system 1000. The system 1000 may include two or more of the systems 100 (shown in FIG. 1) described above. The system 1000 includes a plurality of sets 1002, 1004 of processing chambers 1006 coupled with each other. The sets 1002, 1004 include an input set 1002 of the processing chambers 1006 and an output set 1004 of the processing chambers 1006. The input set 1002 and the output set 1004 are fluidly coupled by a bridge chamber 1008. In one embodiment, the input set 1002 and the output set 1004 may be sealed to the bridge chamber 1008 such that fluids (e.g., gases) and/or the existence of a low pressure atmosphere (e.g., an atmosphere less than 1 atm or a vacuum) may be maintained within an interior volume that is defined by the input set 1002, the output set 1004, and the bridge chamber 1008.

The processing chambers 1006 in each set 1002, 1004 are fluidly coupled with each other. For example, the processing chambers 1006 in that are adjacent to each other may be sealed to each other such that fluids and/or the existence of a low pressure atmosphere may be maintained within an interior volume that is defined by the interconnected processing chambers 1006. In one embodiment, openings and/or gates or doors may exist between adjacent processing chambers 1006 to allow for a device 1010 and/or a carrying carrier 1012 to move between the processing chambers 1006. The device 1010 may represent a semiconductor device, such as a photovoltaic device, and the carrying carrier 1012 may include one or more components that mechanically support the device 1010 but are not included as part of the device 1010 when manufacturing of the device 1010 is completed. In one embodiment, the device 1010 includes or is represented by one or more of the solar modules 900 and/or 1100 shown in FIGS. 9 and/or 11.

The input set 1002 and the output set 1004 of processing chambers 1006 perform various processing steps or operations in the formation of a semiconductor device, such as a photovoltaic device. For example, some processing chambers 1006 may heat the device 1010 (such as to grow an oxide layer, increase a level of crystallinity in one or more semiconductor layers in the device 1010, cause diffusion of dopants or other species into the device 1010, and the like), some processing chambers 1006 may deposit layers onto the device 1010 (such as a semiconductor layer doped with a p-type dopant or an n-type dopant, or an intrinsic semiconductor layer), some processing chambers 1006 may etch portions of the device 1010 (such as to define individual photovoltaic cells in a photovoltaic module), and the like.

One or more conveyance subsystems (such as the conveyance subsystem 114 described above) may be provided to move the device 1010 between the processing chambers 1006. For example, a first conveyor 1014 (such as a conveyor belt connected to a motor) may extend through the processing chambers 1006 in the input set 1002, a second conveyor 1016 may extend through the bridging chamber 1008, and a third conveyor 1018 may extend through the processing chambers 1006 in the output set 1004. The first conveyor 1014 moves the device 1010 sequentially through the processing chambers 1006 of the input set 1002 to the bridging chamber 1008. The second conveyor 1016 moves the device 1010 from the input set 1002 of processing chambers 1006 to the output set 1004 of processing chambers 1006. The third conveyor 1018 moves the device 1010 from the bridging chamber 1008 and through the output set 1004 of processing chambers 1006. For example, during processing of the device 1010, the system 1000 may generally move the device 1010 through the processing chambers 1006 in the input set 1002 along an input processing direction 1022. Once the device 1010 has moved through the processing chambers 1006 of the input set 1002, the system 1000 transfers the device 1010 between the input set 1002 and the output set 1004 by generally moving the device 1010 in a transfer direction 1024. The device 1010 may then move through the processing chambers 1006 of the output set 1004 along an output processing direction 1026.

In the illustrated embodiment, the transfer direction 1024 is transverse to the input processing direction 1022 and the output processing direction 1026. For example, the processing chambers 1006 in the input set 1002 can be linearly aligned with each other in a first direction (e.g., the input processing direction 1022) and the processing chambers 1006 in the output set 1002 can be linearly aligned with each other in a second direction (e.g., the output processing direction 1026), with both the first and second directions being perpendicular to the transfer direction 1024. The input processing direction 1022 and the output processing direction 1026 can be parallel to each other and oriented in opposite directions, as shown in FIG. 10. Alternatively, the input processing direction 1022 and the output processing direction 1026 can be parallel to each other and/or oriented in the same direction. For example, the processing chambers 1006 of the output set 1004 may be disposed on an opposite side of the bridging chamber 1008 than what is shown in FIG. 10, with the output processing direction 1026 oriented in the same direction as the input processing direction 1022.

In operation, the device 1010 (or a substrate of the device 1010) is placed onto the substrate 1212 and loaded into a first processing chamber 1006A (also referred to as a loading or input chamber) of the input set 1002 of processing chambers 1006. The device 1010 may be manually or automatically loaded from a staging container or tray 1020 that holds the device 1010 prior to processing. The first processing chamber 1006A may close so that a. low pressure atmosphere can be established. The device 1010 and substrate 1212 can remain in the first processing chamber 1006A until a subsequent, or neighboring, second processing chamber 1006B is ready to receive the device 1010 and substrate 1212. In one embodiment, several devices 1010 can be concurrently processed by the system 1000. For example, multiple or all of the processing chambers 1006 may have a different device 1010 (e.g., separate devices being fabricated similarly or identically).

Each device 1010 may remain in each separate processing chamber 1006 until the processing of the device 1010 in that processing chamber 1006 is complete and/or until the subsequent processing chamber 1006 (e.g., the next processing chamber 1006 that the device 1010 is to move into) is available. For example, if a first processing chamber 1006 is to heat the device 1010 at a temperature set point and/or for a designated time period, then the device 1010 may remain in the first processing chamber 1006 until the device 1010 is so heated and/or until the neighboring processing chamber 1006 disposed downstream of the first processing chamber 1006 (along the input processing direction 1022 or the output processing direction 1026, as applicable) is available to receive the device 1010 (e.g., when the processing of another device 1010 in the neighboring processing chamber 1006 has completed). The devices 1010 may then move into the next or neighboring processing chambers 1006 disposed downstream of the current processing chambers 1006 in which the devices 1010 are located. The devices 1010 may then be processed by the neighboring processing chambers 1006. This sequential processing and moving of the devices 1010 occurs until the devices 1010 have moved and/or been processed by the processing chambers 1006 in the input set 1002 of processing chambers 1006, have moved from the input set 1002 to the output set 1004 of processing chambers 1006, and have moved and/or been processed by the processing chambers 1006 in the output set 1004. A device 1010 that has so moved through the system 1000 may then be removed from the system 1000 by removing the device 1010 and/or carrier 1012 from an output chamber 1006B of the processing chambers 1006.

Several devices 1010 may be in the processing chambers 1006 at the same time. For example, when a first device 1010 is being processed in a first processing chamber 1006, a second device 1010 may be in a neighboring (or non-neighboring) second processing chamber 1006 being processed at the same time, a third device 1010 may be in a third processing chamber 1006, and so on. When the processing of the devices 1010 in the respective processing chambers 1006 is complete, the devices 1010 may concurrently or simultaneously move to the next or neighboring processing chambers 1006 along the corresponding direction 1022, 1024, or 1026.

The orientation of the processing chambers 1006 shown in FIG. 10 can allow for a reduction in the amount or processing components that are used to process the device 1010 in the system 1000. For example, one or more RF generators, vacuum pumps, gas sources (similar to components 300 shown in FIG. 3) can be positioned between the input set 1002 of processing chambers 1006 and the output set 1004 of processing chambers 1006. These components can be connected to one or more processing chambers 1006 in the input set 1002 of processing chambers 1006 at the same time that the components are connected to one or more processing chambers 1006 in the output set 1004 of processing chambers 1006. For example, a gas source that supplies a gas used for deposition of one or more layers of the device 1010 can be concurrently fluidly coupled with a processing chamber 1006 in the input set 1002 and with a processing chamber 1006 in the output set 1004. The gas source can concurrently provide the gas to both of these processing chambers 1006 for deposition of layers in the devices 1010 that are located in the different processing chambers 1006. As another example, a single vacuum pump can be connected to two or more processing chambers 1006 in the input set 1002 and the output set 1004 to concurrently establish low pressure atmospheres in the processing chambers 1006.

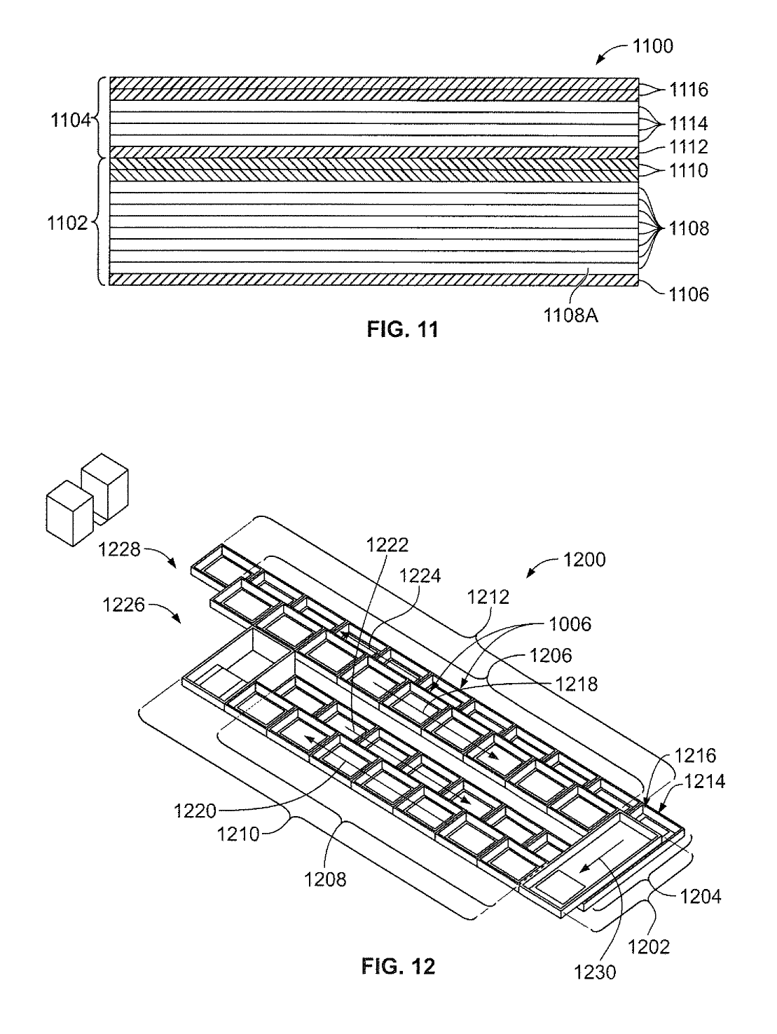

FIG. 11 is a cross-sectional view of a semiconductor layer 1100 in accordance with one embodiment. The semiconductor layer 1100 may represent the semiconductor layer 906 of the solar module 900 shown in FIG. 9. Additionally, the semiconductor layer 1100 may be formed using the system 1000 shown in FIG. 10. For example, the processing chambers 1006 (shown in FIG. 10) may be used to deposit the semiconductor layer 1100, with the device 1010 shown in FIG. 10 representing at least the substrate 902 and the lower electrode 904 shown in FIG. 9.

The semiconductor layer 1100 includes several sublayers that form a lower junction 1102 and an upper junction 1104. In the illustrated embodiment, the sublayers of the lower junction 1102 include a lower sublayer 1106, several (e.g., eight) middle sublayers 1108, and several (e.g., two) upper sublayers 1110, while the upper junction 1104 includes a lower sublayer 1112, several (e.g., four) middle sublayers 1114, and several (e.g., two) upper sublayers 1116. The number of junctions and/or sublayers is provided merely as an example. Different numbers of junctions (e.g., one or more than two) and/or sublayers than what is shown in FIG. 11 may be used in connection with one or more embodiments.

With continued reference to the solar module 900 shown in FIG. 9 and the system 1000 shown in FIG. 10, in one embodiment, the substrate 902 with the lower electrode 904 can be placed onto the carrier carrier 1012 shown in FIG. 10 and loaded into the input chamber 1006A of the system 1000 shown in FIG. 1. The substrate 902 and lower electrode 904 may be moved by the first conveyor 1014 from the input chamber 1006A to the other processing chambers 1006 in the input set 1002, as described above. Once the substrate 902 and lower electrode 904 have moved from the input chamber 1014 to another chamber 1006, another substrate 902 with a lower electrode 904 may be placed into the input chamber 1014, as described above.

In the illustrated embodiment, a plurality of the processing chambers 1006 in the input set 1002 may be heating chambers 1006B, 1006C that heat the substrate 902 and lower electrode 904 to a designated temperature and/or for a designated time. After the substrate 902 and lower electrode 904 have been so heated, the substrate 902 and lower electrode 904 may move into a first deposition chamber 1006D of the processing chambers 1006. The first deposition chamber 1006D may deposit the lower sublayer 1106 of the semiconductor multilayer structure 1100 shown in FIG. 11 onto the lower electrode 904. For example, the first deposition chamber 1006D may be a plasma enhanced chemical vapor deposition (PECVD) or other CVD chamber that deposits an n-doped semiconductor layer onto the lower electrode 904.

After the lower sublayer 1106 is deposited, the system 1000 may move the device 1010 (e.g., the substrate 902, the lower electrode 904, and the lower sublayer 1106) to the next processing chamber 1006, such as a second deposition chamber 1006E. The second deposition chamber 1006E may deposit a first middle sublayer 1108, such as the middle sublayer 1108A, onto the lower sublayer 1106. After the first middle layer 1108A is deposited, the device 1010 (e.g., the substrate 902, the lower electrode 904, the lower sublayer 1106, and the first middle layer 1108A) is moved to the subsequent processing chamber 1006, such as a third deposition chamber 1006F. The device 1010 may continue to move to the processing chambers 1006 on that additional sublayers 1108, 1110, 1112, 1114, and 1116 are deposited. In the illustrated embodiment, each of the processing chambers 1006 that deposits a sublayer may deposit a sublayer of approximately the same thickness as the sublayers deposited by the other processing chambers 1006. For example, the device 1010 may remain in each processing chamber 1006 for an equivalent amount of time so that the sublayers that are concurrently deposited on different devices 1010 in different processing chambers 1006 are approximately the same thickness. Alternatively, one or more processing chambers 1006 may deposit thicker or thinner sublayers than one or more other processing, chambers 1006 and/or the device 1010 may spend a longer or shorter period of time in one or more of the processing chambers 1006 than in one or more other processing chambers 1006.

The number of processing chambers 1006 that are used to deposit the different sublayers may be based on the total thickness of each of the groups of sublayers. For example, the lower sublayer 1106 may be a first group that forms an n-doped layer in a lower NIP junction (or up-doped layer in a lower PIN junction), the middle sublayers 1108 may be a second group that forms an intrinsic layer in the lower NIP or lower PIN junction, the upper sublayers 1110 may be a third group that forms the p-doped layer in the lower NIP junction or the n-doped layer in the lower PIN junction. The lower sublayer 1112 may be a fourth group that forms an n-doped layer in an upper NIP junction (or a p-doped layer in an upper PIN junction), the middle sublayers 1114 may be a fifth group that forms an intrinsic layer in the upper NIP junction or the upper PIN junction, and the upper sublayers 1116 may be a sixth group that forms a p-doped layer in the upper NIP junction or an n-doped layer in the upper PIN junction. The number of processing chambers 1006 used to deposit the sublayers in each group may be based on the thickness of the layers formed by the sublayers. For example, in the illustrated embodiment, the number of processing chambers 1006 used to deposit the intrinsic layer of the lower junction 1102 (e.g., the processing chambers 1006E-L that deposit the sublayers 1108) may be eight times as many as the number of processing chambers 1006 that are used to deposit the n-doped layer of the same lower junction 1102 (e.g., the processing chamber 10061) used to deposit the sublayer 1106). The number of processing chambers 1006 used to deposit the p-doped layer of the same lower junction 1102 the processing chambers 1006M-N) may be one fourth of the number of processing chambers 1006 used to deposit the intrinsic layer of the lower junction 1102 (e.g., the processing chambers 1006E-L) and/or twice as many as the number of processing chambers 1006 used to deposit the n-doped layer of the lower junction 1102 (e.g., the processing chamber 1006D).

With respect to the upper junction 1104, the number of processing chambers 1006 used to deposit the intrinsic layer (e.g., the processing chambers 1006Q-T) may be four times as many as the number of processing chambers 1006 used to deposit the n-doped layer of the upper junction 1104 (e.g., the processing chamber 1006O) and twice as many as the number of processing chambers 1006 used to deposit the p-doped layer of the upper junction 1104 (e.g., the processing chambers 1006U-V). The number of processing chambers 1006 and the relative thicknesses of the layers in the junctions 1102, 1104 described above are provided as examples and are not intended to be limiting on all embodiments of the presently described inventive subject matter.

Once the device 1010 is removed from the system 1000, the upper and lower junctions 1104, 1102 may be deposited onto the lower electrode 904 shown in FIG. 9. The upper and lower junctions 1104, 1102 can form the active semiconductor material of the solar module 900 (e.g., the semiconductor layer 906). The system 1000 may be used to deposit the semiconductor layer 906, such as a tandem semiconductor layer 906 having the two junctions 1102, 1104, without removing the device (e.g., the substrate 902, lower electrode 904, and any other layers deposited thereon) from the system 1000 and/or exposing the device to atmospheric conditions outside of the system 1000.

The inclusion of the bridging chamber 1008 in the system 1000 can allow for more processing chambers 1006 to be included in the system 1000. The bridging chamber 1008 can allow for a larger number of processing chambers 1006 to be fluidly coupled with each other such that a low pressure atmosphere can be maintained between or among the connected processing chambers 1006. For example, the number of processing chambers 1006 that can be fluidly coupled and linearly aligned with each other can be limited due to the thermal expansion of the individual processing chambers 1006 during the deposition of the sublayers 11106, 1108, 1110, 11112, 1114, 1116. The deposition of the sublayers 1106, 1108, 1110, 1112, 1114, 1116 may occur at elevated temperatures such that the processing chambers 1006 (e.g., in the input set 1002 or in the output set 1004) may each expand toward each other and close the distances between each other. If the amount of expansion is significant, then the seals between the neighboring processing chambers 1006 may be relatively large. When the number of processing chambers 1006 that are linearly aligned with each other becomes too large, the distance between the processing chambers 1006 may need to be so large (e.g., to prevent the processing chambers 1006 from expanding too much and damaging each other) that the seal between the chambers 1006 also may need to be significantly thick. However, the seal cannot be too thick as an adequate seal may not be able to be maintained in order to keep a low pressure atmosphere in the chambers 1006.

In one embodiment, the number of processing chambers 1006 that can be linearly aligned and fluidly coupled with each other (while maintaining seals between the chambers 1006) in the input set 1002 and/or the output set 1004 may be limited to twenty or fewer processing chambers 1006. Alternatively, the number of processing chambers 1006 that can be linearly aligned and fluidly coupled with each other in the input set 1002 and/or the output set 1004 may be limited to thirteen or fewer processing chambers 1006. These examples of limits on the number of processing chambers 1006 in each set 1002, 1004 are based on upper limits of the seals between the processing chambers 1006 when the chambers 1006 in each set thermally expand.

By coupling the input set 1002 and the output sets 1004 of the processing chambers 1006 with the bridging chamber 1008, a larger number of processing chambers 1006 may be fluidly coupled with each other relative to a system that does not include the bridging chamber 1008. For example, the thermal expansion between the processing chambers 1006 may limit the number of processing chambers 1006 that can be linearly aligned with each other such that the entire semiconductor layer 906 (e.g., the lower junction 1102, the upper junction 1104, or both the lower and upper junctions 1102, 1104) may not be able to be deposited without removing the device from the processing chambers 1006 and placing the device into another group of the processing chambers 1006 to complete the deposition of the semiconductor layer 906. Because the thermal expansion of the processing chambers 1006 may be additive along the linear direction that the processing chambers 1006 are aligned, using the bridging chamber 1008 to couple different sets of processing chambers 1006 can allow for an increased number of processing chambers 1006 to be included in the system 1000. For example, if only a designated number of the processing chambers 1006 can be linearly aligned and coupled with each other due to the thermal expansion (e.g., thirteen or less chambers 1006), the bridging chamber 1008 can allow for up to the designated number of the processing chambers 1006 in the input set 1002 to be fluidly coupled with up to the designated number of the processing chambers 1006. Additional bridging chambers 1008 may be provided to further increase the number of processing chambers 1006 that are fluidly coupled with each other.

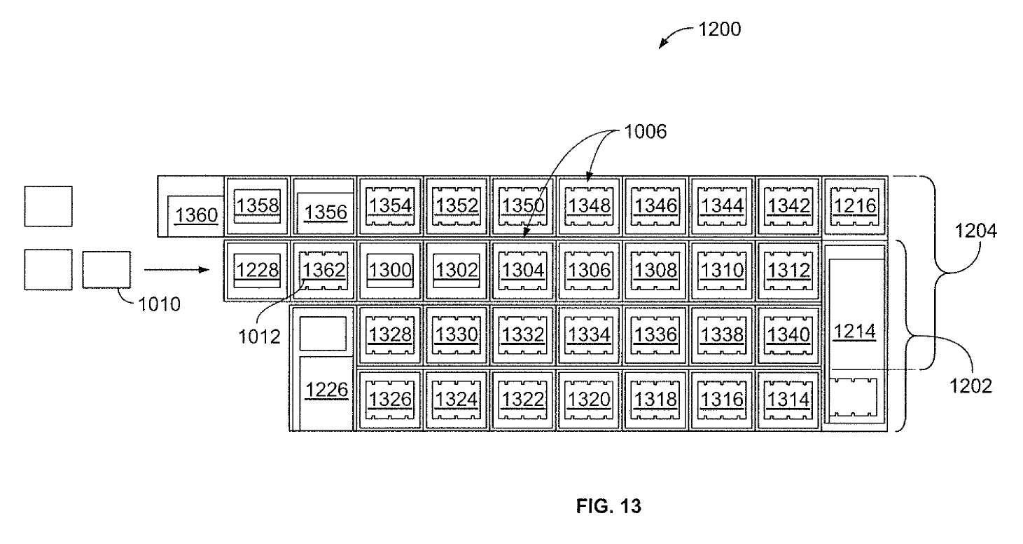

FIG. 12 is a cross-sectional view of another embodiment of a multi-chamber system 1200. The view shown in FIG. 12 presents the bottom half of the processing chambers 1006 in the system 1200. FIG. 13 is a top view of the system 1200 shown in FIG. 12. The system 1200 may include two or more of the systems 100 (shown in FIG. 1) and/or the systems 1000 (shown in FIG. 10) described above. In the illustrated embodiment, the system 1200 is a multi-level system having a first, or upper, processing circuit 1202 and a second, or lower, processing circuit 1204. The processing circuits 1202, 1204 may each be similar to one of the systems 1000. For example, each processing circuit 1202, 1204 includes an input set 1206, 1208 and an output set 1210, 1212 of processing chambers 1006 that are fluidly coupled with each other. As described above, the processing chambers 1006 in the input sets 1206, 1208 and the output sets 1210, 1212 may be linearly aligned with each other to allow for a conveyor (not shown in FIGS. 12 and 13, but may be similar to the conveyors 1014, 1016, 1018 shown in FIG. 10) to linearly move devices 1010 through the upper processing circuit 1202 and the lower processing circuit 1204. As shown in FIG. 12, the upper processing circuit 1202 is disposed above the lower processing circuit 1204. Alternatively, the processing circuits 1202, 1204 may be disposed side-by-side (such as in an S-shaped configuration) and/or may otherwise be arranged relative to each other.

The input set 1206 and the output set 1210 of the upper processing circuit. 1202 are fluidly coupled with each other by an upper bridging chamber 1214. The input set 1208 and the output set 1212 of the tower processing circuit 1204 are fluidly coupled with each other by a lower bridging chamber 1216. The bridging chambers 1214, 1216 may be similar to the bridging chamber 1008 (shown in FIG. 10). For example, the bridging chambers 1214, 1216 may maintain a low pressure atmosphere and/or elevated temperature in the volumes defined by the processing chambers 1006 of the input sets 1206, 1208 and the output sets 1210, 1212 such that the devices 1010 moving through the bridging chambers 1214, 1216 between the input sets 1206, 1208 and output sets 1210, 1212 of processing chambers 1006 remain in the same or substantially same atmosphere and/or temperature.

Similar to the system 1000 shown in FIG. 10, the processing chambers 1006 in the sets 1206, 1208, 1210, 1212 of the system 1200 are linearly aligned with each other. For example, the processing chambers 1006 in the input set 1206 of the upper processing circuit 1202 may be linearly aligned with each other along an upper input direction 1218, the processing chambers 1006 in the output set 1208 of the upper processing circuit 1202 may be linearly aligned with each other along an upper output direction 1220, the processing chambers 1006 in the input set 1210 of the lower processing circuit 1204 may be linearly aligned with each other along a lower input direction 1222, and the processing chambers 1006 in the output set 1212 of the lower processing circuit 1204 may be linearly aligned with each other along a lower output direction 1224. In the illustrated embodiment, the input direction 1218, 1222 and the output direction 1220, 1224 in each processing circuit 1202, 1204 may be oriented in opposite directions. Alternatively, one or more of the input directions 1218, 1222 and one or more of the output directions 1220, 1224 may be oriented in the same direction. The input directions 1218, 1222 may be oriented in the same direction and the output directions 1220, 1224 may be oriented in the same direction. Although not shown in FIG. 12, conveyor subsystems (e.g., similar to the conveyor subsystems 114, 1014, 1016, 1018) may be included in the system 1200 to move the devices 1010 through the processing chambers 1006 of the system 1200, similar to as described above in connection with the system 1000.

The system 1200 includes a transition chamber 1226 that transfers the devices 1010 between the processing circuits 1202, 1204. The transition chamber 1226 fluidly couples the processing chambers 1006 of the upper processing circuit 1202 with the processing chambers 1006 of the lower processing circuit 1204. When a device 1010 has moved through the upper processing circuit 1202, the device 1010 may be loaded into the transition chamber 1226 (e.g., by a conveyor subsystem). The transition chamber 1226 may move the device 1010 to the lower processing circuit 1204, such as by lowering the device 1010 to the plane of the lower processing circuit 1204. The device 1010 may then be moved (e.g., by a conveyor subsystem) to the lower input set 1210 of the processing chambers 1006. The device 1010 may then move through the processing chambers 1006 of the lower processing circuit 1204.

For example, the device 1010 may be loaded into an input processing chamber 1228 of the upper processing circuit 1202. The device 1010 may then sequentially move along the upper input direction 1218 through the processing chambers 1006 to the upper bridging chamber 1214. The device 1010 may then move in an upper transfer direction 1230 in the upper bridging chamber 1214 to the upper output set 1210 of processing chambers 1006. In the illustrated embodiment, the upper transfer direction 1230 is perpendicular to the upper input direction 1218 and the upper output direction 1220. The device 1010 then moves through the processing chambers 1006 of the upper output set 1210 along the upper output direction 1220 to the transition chamber 1226. The transition chamber 1226 lowers the device 1010 to the lower processing circuit 1204. For example, the transition chamber 1226 may lower the device 1010 in a vertical direction that is oriented perpendicular to the input and output directions 1218, 1220, 1222, 1224 and the transfer direction 1230. Alternatively, if the positions of the upper and lower processing circuits 1202, 1204 are switched, the transition chamber 1226 may raise the device 1010 in the vertical direction.

Once the device 1010 has been lowered to the lower processing circuit 1204 in the transition chamber 1226, the device 1010 may be moved through the processing chambers 1006 of the lower input set 1208 along the lower input direction 1222, such as by a conveyor subsystem. In the illustrated embodiment, the processing chambers 1006 in the lower input set 1208 are disposed below the processing chambers 1006 in the upper output set 12010. The device 1010 may move through the processing chambers 1006 of the lower input set 1208 to the lower bridging chamber 1216. The device 1010 may laterally move from the lower input set 1208 to the lower output set 1212. For example, a conveyor subsystem (not shown) may move the device 1010 in the lower bridging chamber 1216 in a transfer direction that is oriented opposite to the transfer direction 1230.

Once the device 1010 has been moved by the tower bridging chamber 1216, the device 1010 may be moved (e.g., by a conveyor subsystem) through the processing chambers 1006 of the lower output set 1212 along the lower output direction 1224. The device 1010 is moved to an output chamber 1230 where the device 1010 may be removed from the system 1200. Alternatively, the device 1010 may be moved to another bridging chamber or another transition chamber to move, raise, or lower the device 1010 to another set of processing chambers 1010.

Similar to the system 1000 shown in FIG. 10, different groups of the processing chambers 1006 may deposit different portions of one or more junctions of the semiconductor layer 906 (shown in FIG. 9) of the solar module 900 (shown in FIG. 9). The processing chambers 1006 are labeled 1300 through 1362 in FIG. 13. In the illustrated embodiment, the processing chamber 1300 may heat the device 1010, the processing chamber 1302 may deposit an n-doped layer of a lower NIP junction (or a p-doped layer of a lower PIN junction) of the semiconductor layer 906, the processing chambers 1304 through 1342 of the upper and lower processing circuits 1202, 1204 may deposit an intrinsic layer of the lower NIP junction (or of the lower PIN junction), the processing chamber 1344 of the lower processing circuit 1204 may deposit a p-doped layer of the lower NIP junction (or an n-doped layer of the lower PIN junction), the processing chamber 1346 of the lower processing circuit 1204 may deposit an n-doped layer of an upper NIP junction (or a p-doped layer of the upper PIN junction), the processing chambers 1348 through 1354 may deposit an intrinsic layer of the upper NIP junction (or of the upper PIN junction), and the processing chamber 1356 of the lower processing circuit 1204 may deposit a p-doped layer of the upper NIP junction (or an n-doped layer of the upper PIN junction). The device 1010 may then be removed from the system 1200 from an output chamber 1230 of the system 1200. Alternatively, one or more other layers, junctions, components, and the like of the solar module 900 may be formed using the system 1200, and/or one or more of the processing chambers 1006 of the system 1200 may deposit a different sublayer than what is described above.

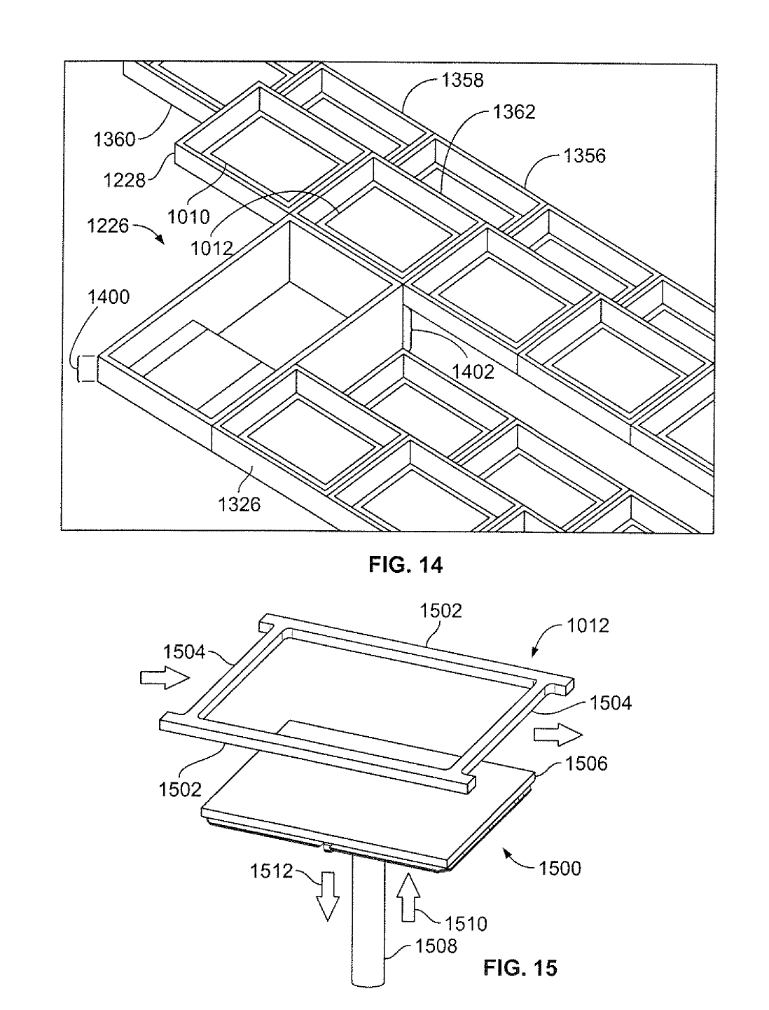

With continued reference to the system 1200 shown in FIGS. 12 and 13, FIG. 14 is a perspective view of the transition chamber 1226 in accordance with one embodiment. The transition chamber 1226 may laterally span between the upper input set 1226 and the upper output set 1210 of the processing chambers 1006. For example, the transition chamber 1226 may have an upper portion 1400 that is fluidly coupled with the processing chamber 1362 of the upper input set 1226 and the processing chamber 1326 of the upper output set 1210. The transition chamber 1226 also may have a lower portion 1402 that is fluidly coupled with the processing chamber 1328 of the lower input set 1208. In one embodiment, the lower portion 1402 of the transition chamber 1226 may be fluidly coupled with the processing chamber 1356 of the lower output set 1212. For example, the lower portion 1402 of the transition chamber 1226 may extend beneath the processing chamber 1362 of the upper processing circuit 1202 to the processing chamber 1356 of the lower processing circuit 1204.

In one embodiment, the devices 1010 being processed by the system 1200 may be separated from the substrates 1212 and/or placed on different substrates 1212 by the transition chamber 1226. For example, a first device 1010 may be carried by a first carrier 1012 through the processing chambers in the upper processing circuit 1202. When the first device 1010 and the first carrier 1012 enter into the transition chamber 1226 from the processing chamber 1326 of the upper processing circuit 1202, the first device 1010 and the first carrier 1012 may laterally move to a position above the tower portion 1402 of the transition chamber 1226. The first device 1010 may be separated from the first carrier 1012 (such as by lifting the first device 1010 above the first carrier 1012). The first carrier 1012 may then move laterally into the processing chamber 1362 of the upper processing circuit 1202. The first device 1010 may be lowered to a different, second carrier 1012 disposed in the lower portion 1402 of the transition chamber 1226. The first device 1010 may then move through the lower processing circuit 1204 white being supported by the second carrier 1012.

The first carrier 1012 may continue to move laterally in the upper portion 1400 of the transition chamber 1226 to the processing chamber 1362 of the upper processing circuit 1202. Another, second device 1010 may be loaded into the processing chamber 1362 from the input chamber 1228 and onto the first carrier 1012 in the processing chamber 1362. For example, the second device 1010 may be inserted into the input chamber 1362 without a substrate but may move to the processing chamber 1362 to be placed onto the first carrier 1012. The second device 1010 may then move through the upper processing circuit 1202 white being supported by the first carrier 1012. The second device 1010 and the first carrier 1012 may separate from each other in the transition chamber 1226, as described above, so that the second device 1010 may move through the lower processing circuit 1204 and the first carrier 1012 can return to the processing chamber 1362 to receive another device 1010.

The second carrier 1012 and the first device 1010 can be moved from the tower portion 1402 of the transition chamber 1226 through the lower processing circuit 1204. When the second carrier 1012 and the first device 1010 arrive in the processing chamber 1356 that is fluidly coupled with the tower portion 1402 of the transition chamber 1226, the first device 1010 may be separated from the second carrier 1012 (e.g., by lifting the first device 1010). The first device 1010 may then move to the processing chambers 1358, 1360 in order to be removed from the system 1200. The second carrier 1012 may laterally move from the processing chamber 1356 into the lower portion 1402 of the transition chamber 1226. For example, the second carrier 1012 may return to a location where another device 1010 may be lowered from the upper portion 1400 of the transition chamber 1226 onto the second carrier 1012 in the tower portion 1402 of the transition chamber 1226. This other device 1010 can then travel through the tower processing circuit 1204 on the second carrier 1012.

As described above, the carriers 1012 may separately remain in the upper or lower processing circuits 1202, 1204 such that each carrier 1012 may only support and move with devices 1010 in the upper processing circuit 1202 or only in the tower processing circuit 1204. Different carriers 1012 may be dedicated to only moving in different processing circuits 1202, 1204. The different processing circuits 1202, 1204 may be associated with different operational conditions, such as temperature and/or pressure. For example, the temperatures and/or pressures inside the processing chambers of the upper processing circuit 1202 may be different (e.g., hotter and/or lower pressure) than the temperatures and/or pressures inside the processing chambers of the tower processing circuit 1202. In order to avoid damage to the carriers 1012 and/or devices 1010 (e.g., thermal shock to the carriers 1012 and/or devices 1010 from changes in temperature of the carriers 1012 or other mechanical damage), the system 1200 may keep the carriers 1012 in a common temperature and/or pressure in each processing circuit 1202, 1204. The transition chambers 1226 may act as temperature transition zones between the processing circuits 1202, 1204.

FIG. 15 is a perspective view of a lift mechanism 1500 and the carrier 1012 in accordance with one embodiment. As shown in FIG. 15, the carrier 1012 may be formed as a frame that defines a perimeter. In the illustrated embodiment, the carrier 1012 has four elongated bodies 1502, 1504 that form a rectangular shape. Alternatively, the bodies 1502, 1504 may form another shape. The device 1010 may sit atop two or more of the bodies 1502, 1504 as the carrier 1012 carries the device 1010 through the system 100, 1000, and/or 1200. For example, the device 1010 may engage and be supported by all of the bodies 1502, 1504, only the longer bodies 1502, or only the shorter bodies 1504. In another embodiment, the carrier 1012 may be formed differently, such as a solid body that does not have an opening between the bodies 1502, 1504.

The lift mechanism 1500 is a device that can change the vertical position of the carrier 1012 and device 1010 on the carrier 1012. The lift mechanism 1500 includes a platform 1506 on which the carrier 1012 sits and an actuator 1508 that extends or retracts to change the vertical position of the platform 1506. For example, the actuator 1508 may be an elongated body or a telescoping body that extends to move the platform 1506 in a first direction 1510 and retracts to move the platform 1506 in an opposite second direction 1512.

The lift mechanism 1500 may be disposed in one or more of the processing chambers 1006 to assist in the processing of the devices 1010. For example, the lift mechanism 1500 may be an electrode in a PECVD chamber that deposits one or more of the sublayers onto the device 1010. In another embodiment, the lift mechanism 1500 may be included in the transition chamber 1226 of the system 1200 shown in FIGS. 12 and 13 to vertically move the device 1010 in the transition chamber 1226. For example, the device 1010 may be separated from the carrier 1012 and placed onto the lift mechanism 1500 for lowering the device 1010 in the transition chamber 1226. In one embodiment, the device 1010 may be separated from the carrier 1012 by grasping exposed sides of the device 1010, applying a suction pressure to the top of the device 1010, or otherwise grasping the device 1010 and separating the device 1010 from the carrier 1012. The carrier 1012 may then be moved from below the grasped device 1010 and the device 1010 can then be placed, such as onto the platform 1506, for vertical movement by the actuator 1508. When the lift mechanism 1500 has moved the device 1010, such as by lowering the device 1010 in the transition chamber 1226, the device 1010 may be grasped again and placed onto another carrier 1012, as described above.

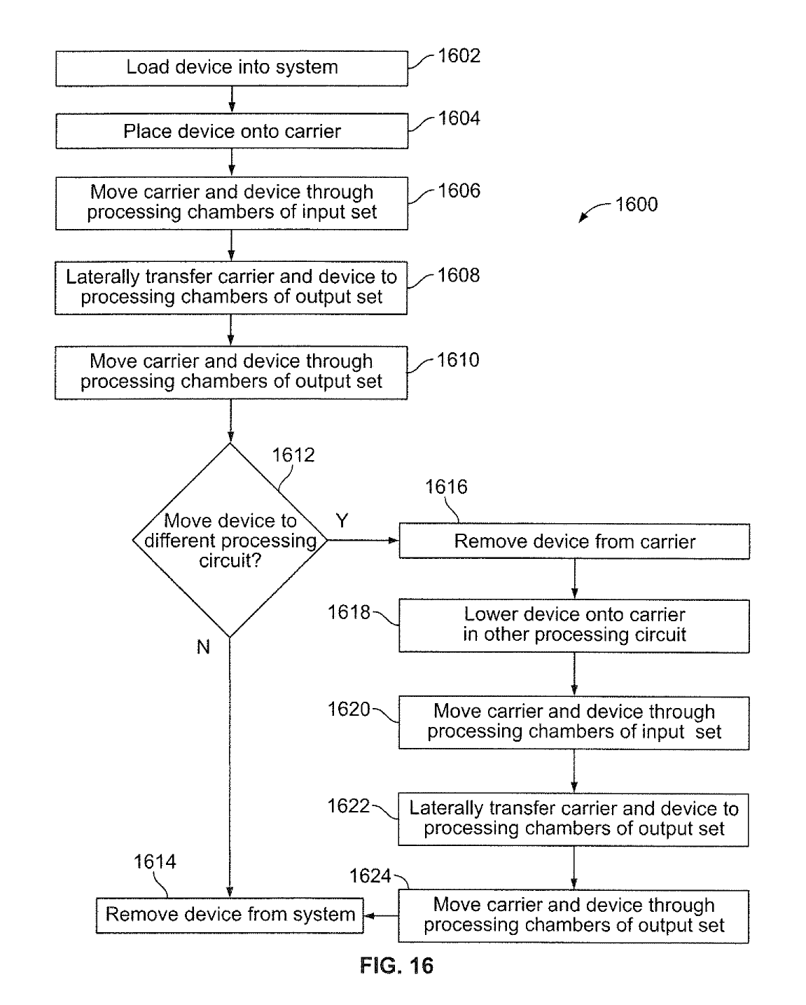

FIG. 16 is a flowchart of one embodiment of a method 1600 for processing a device, such as a photovoltaic or solar module. The method 1600 may be used in conjunction with one or more embodiments of the systems 100, 1000, 1200 shown in FIGS. 1, 10, and 12 for manufacturing the solar module 100 and/or 900.

At 1602, a device is loaded into the system. For example, the device 1010 (such as a glass substrate with a lower electrode layer deposited thereon) can be loaded into the input chamber of the system 100, 1000, and/or 1200. At 1604, the device is placed onto a carrier. For example, the device 1010 may be placed onto the carrier 1012, such as by grasping the device 1010 and lowering the device 1010 onto the carrier 1012.

At 1606, the carrier and device move through the processing chambers of an input set of processing chambers. As described above, the carrier 1012 and the device 1010 may sequentially move through the processing chambers in an input set of processing chambers of a first processing circuit. The carrier 1012 and device 1010 may temporarily stop in each processing chamber and be processed in that chamber. For example, the device 1010 may stop so that a sublayer can be deposited onto the device 1010, as described above.

At 1608, the carrier 1012 and device 1010 are laterally transferred from the input set of processing chambers to the processing chambers of an output set of processing chambers in the first processing circuit. As described above, a bridging chamber may laterally move the carrier 1012 and device 1010 from the input set to the output set of processing chambers in the same processing circuit.

At 1610, the carrier and device move through the processing chambers of the output set of processing chambers. As described above, the carrier 1012 and device 1010 may temporarily stop in each processing chamber and be processed in that chamber. For example, the device 1010 may stop so that a sublayer can be deposited onto the device 1010, as described above.

At 1612, a determination is made as to whether the device is to be moved to a different processing circuit. For example, a decision may be made as to whether the device 1010 is to be raised, lowered, or otherwise moved from the first processing circuit (e.g., the upper processing circuit 1202) to another, second processing circuit (e.g., the lower processing circuit 1204). If the device is not to be moved to another processing circuit (e.g., the processing of the device is complete or there is no other processing circuit), then flow of the method 1600 flows to 1614. If the device is to be moved to another processing circuit (such as the lower processing circuit 1204), then flow of the method 1600 flows to 1616.

At 1616, the device is separated from the carrier. For example, the device 1010 may be grasped and lifted from the carrier 1012 while the carrier is removed from beneath the device 1010. Alternatively, the carrier 1012 may be slid from beneath the device 1010 so that the carrier 1012 is no longer below the device 1010.

At 1618, the device is towered onto another carrier. For example, the device 1010 may be lowered in the transition chamber 1226 onto a carrier 1012 in the lower processing circuit 1204. In another embodiment, the device is not separated from the carrier at 1616 and the device is not lowered onto another carrier at 1618. For example, both the device and the carrier may move from the first processing circuit to the second processing circuit together.

At 1620, the carrier and device move through the processing chambers of an input set of processing chambers in the processing circuit. As described above, the carrier 1012 and the device 1010 may sequentially move through the processing chambers in an input set of processing chambers of the second processing circuit. The carrier 1012 and device 1010 may temporarily stop in each processing chamber and be processed in that chamber. For example, the device 1010 may stop so that a sublayer can be deposited onto the device 1010, as described above.

At 1622, the carrier 1012 and device 1010 are laterally transferred from the input set of processing chambers to the processing chambers of an output set of processing chambers in the second processing circuit. As described above, a bridging chamber may laterally move the carrier 1012 and device 1010 from the input set to the output set of processing chambers in the same processing circuit.

At 1624, the carrier and device move through the processing chambers of the output set of processing chambers. As described above, the carrier 1012 and device 1010 may temporarily stop in each processing chamber and be processed in that chamber. For example, the device 1010 may stop so that a sublayer can be deposited onto the device 1010, as described above.

After 1624, flow of the method 1600 flows to 1614. At 1614, the device is removed from the system. For example, the device 1010 may be separated from the carrier and removed from an output processing chamber of the system with the processing of the device by the system being complete (e.g., the semiconductor layer or junctions being deposited onto the device 1010). Alternatively, if one or more additional processing circuits are provided in the system, the device may be moved to the additional processing circuit(s), similar to as described above in connection with 1612 through 1618.

In another embodiment, a system (e.g., a system for forming one or more semiconductor layers on a device) includes an input set and an output set of processing chambers. The processing chambers of the input set are configured to be fluidly coupled and linearly aligned with each other along an input direction. The processing chambers of the input set are configured to process and move a device between the processing, chambers of the input set along the input direction with the processing chambers of the input set separately processing the device when the device is located in each of the processing chambers of the input set. The processing chambers of the output set are configured to be fluidly coupled and linearly aligned with each other along an output direction, the processing chambers of the output set configured to process and move the device between the processing chambers of the output set along the output direction with the processing chambers of the output set separately processing the device when the device is located in each of the processing chambers of the output set.

In another aspect, the system also includes a plurality of one or more of the input set or the output set of processing chambers disposed parallel to each other and providing at least one common processing function.

In another aspect, the processing chambers that provide the at least one common processing function share at least one of a common control component or a common supply component.

In another aspect, at least one of the input set or the output set of processing chambers includes twenty or less processing chambers.

In another aspect, at least one of the input set or the output set of processing chambers includes thirteen or less processing chambers.

In another aspect, at least one of the processing chambers is configured to deposit a semiconductor material on the device.

In another aspect, the processing chambers of the input set and the processing chambers of the output set are arranged in groups with the processing chambers in each group configured to deposit one or more sublayers of semiconductor material to form one or more semiconductor junctions on the device.

In another aspect, the input direction and the output direction are oriented in opposite directions.

In another aspect, the input direction and the output direction are oriented in a common direction.

In another aspect, e system also includes abridging chamber configured to be fluidly coupled with one or more of the processing chambers of the input set and one or more of the processing chambers of the output set. The bridging chamber also is configured to receive the device from the one or more of the processing chambers of the input set and move the device along a transfer direction to the one or more of the processing chambers of the output set. The transfer direction is oriented transverse to at least one of the input direction or the output direction.

In another aspect, the transfer direction is perpendicular to at least one of the input direction or the output direction.

In another aspect, the bridging chamber is configured to be fluidly coupled with the processing chambers of the input set and the processing chambers of the output set to maintain at least one of an elevated temperature or a reduced pressure atmosphere below one atmosphere in the processing chambers and the bridging chamber.

In another aspect, the input set of the processing chambers, the bridging chamber, and the output set of the processing chambers form a first processing circuit, and further comprising an additional input set of the processing chambers, an additional bridging chamber, an additional output set of the processing chambers, and a transition chamber that are configured to be fluidly coupled with each other to form a second processing circuit.

In another aspect, the transition chamber is configured to be fluidly coupled with one or more of the processing chambers in the output set of the first processing circuit to receive the device and to move the device to the additional input set of the processing chambers. The additional input set of the processing chambers is configured to process and move the device in an additional input direction to the additional bridging chamber. The additional bridging chamber is configured to move the device in an additional transfer direction to one or more of the processing chambers of the additional output set. The processing chambers of the additional output set is configured to process and move the device in an additional output direction.

In another aspect, the first processing circuit is disposed above the second processing circuit or the first processing circuit is disposed below the second processing circuit, and the transition chamber is configured to lift or lower the device between the first processing circuit and the second processing circuit.

In another aspect, the processing chambers in the first processing circuit are configured to maintain at least one of a first temperature or a first pressure inside the processing chambers of the first processing circuit for processing the device and the processing chambers in the second processing circuit are configured to maintain at least one of a different, second temperature or a different, second pressure inside the processing chambers of the second processing circuit for processing the device.

In another embodiment, another system (e.g., a system for processing a module) includes a first processing circuit, a second processing circuit, and a transition chamber. The first processing circuit has a first input set of processing chambers configured to be fluidly coupled and linearly aligned with each other along a first input direction, a first output set of the processing chambers configured to be fluidly coupled and linearly aligned with each other along a first output direction, and a first bridging chamber extending between the first input set of processing chambers and the first output set of processing chambers. The second processing circuit has a second input set of processing chambers configured to be fluidly coupled and linearly aligned with each other along a second input direction, a second output set of the processing chambers configured to be fluidly coupled and linearly aligned with each other along a second output direction, and a second bridging chamber extending between the second input set of processing chambers and the second output set of processing chambers. The transition chamber is configured to be fluidly coupled with the first processing circuit and the second processing circuit. The first processing circuit is configured to process and move a semiconductor-based device through the processing chambers of the first processing circuit along the first input direction, the first transfer direction, and the first output direction. The transition chamber is configured to move the device to the second processing circuit. The second processing circuit is configured to process and move the device through the processing chambers of the second processing circuit along the second input direction, the second transfer direction, and the second output direction to deposit one or more semiconductor layers on the device.

In another aspect, the processing chambers are arranged in groups with the processing chambers in each group configured to deposit one or more sublayers of semiconductor material to form one or more semiconductor junctions on the device.

In another aspect, the first input direction and the first output direction are oriented in opposite directions or the second input direction and the second output direction are oriented in opposite directions.

In another aspect, the first transfer direction is perpendicular to at least one of the first input direction or the first output direction, or the second transfer direction is perpendicular to at least one of the second input direction or the second output direction.

In another aspect, the first bridging chamber and the second bridging chamber are configured to be fluidly coupled with the processing chambers of the first processing circuit and the second processing circuit, respectively, to maintain at least one of an elevated temperature or a reduced pressure atmosphere below one atmosphere in the first processing circuit and the second processing circuit.

In another aspect, the processing chambers of the first processing circuit are configured to maintain a first temperature for processing the device and the processing chambers of the second processing circuit are configured to maintain a different, second temperature for processing the device.

In another aspect, the transition chamber is configured to receive the device and a first carrier from the processing chambers in the first processing circuit, separate the device from the first carrier, move the device to a second carrier in the second processing circuit, and move the device and the second carrier into the processing chambers of the second processing circuit.

In another aspect, the transition chamber is configured to move the first carrier to one or more of the processing chambers in the first input set of the first processing chambers to that another device is placed onto a different, second carrier for being carried through the processing chambers of the first processing circuit.

In another aspect, the transition chamber is configured to receive the second carrier from the processing chambers of the second processing circuit and place another device onto the second carrier for being carried through the processing chambers of the second processing circuit.

In another embodiment, a multi-chamber system includes a plurality of chambers linearly aligned with each other, wherein each chamber performs a different processing function or step in a manufacturing process of a photovoltaic module.

In another aspect, the system also includes a conveyor subsystem that linearly moves the photovoltaic module between the chambers.

In another aspect, a first chamber deposits a conductive lower electrode of the photovoltaic module, a different, second chamber deposits a semiconductor layer, and a different, third chamber deposits a conductive upper electrode of the photovoltaic module.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the inventive subject matter without departing from its scope. While the dimensions, types of materials and coatings described herein are intended to define the parameters of the inventive subject matter, they are by no means limiting and are exemplary embodiments. Many other embodiments will be apparent to those of skill in the art upon reviewing the above description. The scope of the inventive subject matter should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. §112, sixth paragraph, unless and until such claim limitations expressly use the phrase “means for” followed by a statement of function void of further structure.

This written description uses examples to disclose the various embodiments of the inventive subject matter, including the best mode, and also to enable any person of ordinary skill in the art to practice the various embodiments of the inventive subject matter, including making and using any devices or systems and performing any incorporated methods. The patentable scope of the various embodiments of the inventive subject matter is defined by the claims, and may include other examples that occur to those of ordinary skill in the art. Such other examples are intended to be within the scope of the claims if the examples have structural elements that do not differ from the literal language of the claims, or if the examples include equivalent structural elements with insubstantial differences from the literal languages of the claims.

What is claimed is:

1. A system comprising:
an input set of processing chambers configured to be fluidly coupled and linearly aligned with each other along an input direction, the processing chambers of the input set configured to process and move a device between the processing chambers of the input set along the input direction with the processing chambers of the input set separately processing the device when the device is located in each of the processing chambers of the input set; and
an output set of processing chambers configured to be fluidly coupled and linearly aligned with each other along an output direction, the processing chambers of the output set configured to process and move the device between the processing chambers of the output set along the output direction with the processing chambers of the output set separately processing the device when the device is located in each of the processing chambers of the output set.

2. The system of claim 1, further comprising a plurality of one or more of the input set or the output set of processing chambers disposed parallel to each other and providing at least one common processing function.

3. The system of claim 3, wherein the processing chambers that provide the at least one common processing function share at least one of a common control component or a common supply component.

4. The system of claim 1, wherein at least one of the input set or the output set of processing chambers includes twenty or less processing chambers.

5. The system of claim 1, wherein at least one of the input set or the output set of processing chambers includes thirteen or less processing chambers.

6. The system of claim 1, wherein at least one of the processing chambers is configured to deposit a semiconductor material on the device.

7. The system of claim 1, wherein the processing chambers of the input set and the processing chambers of the output set are arranged in groups with the processing chambers in each group configured to deposit one or more sublayers of semiconductor material to form one or more semiconductor junctions on the device.

8. The system of claim 1, wherein the input direction and the output direction are oriented in opposite directions.

9. The system of claim 1, wherein the input direction and the output direction are oriented in a common direction.

10. The system of claim 1, further comprising of a bridging chamber configured to be fluidly coupled with one or more of the processing chambers of the input set and one or more of the processing chambers of the output set, the bridging chamber configured to receive the device from the one or more of the processing chambers of the input set and move the device along a transfer direction to the one or more of the processing chambers of the output set, wherein the transfer direction is oriented transverse to at least one of the input direction or the output direction.

11. The system of claim 10, wherein the transfer direction is perpendicular to at least one of the input direction or the output direction.

12. The system of claim 10, wherein the bridging chamber is configured to be fluidly coupled with the processing chambers of the input set and the processing chambers of the output set to maintain at least one of an elevated temperature or a reduced pressure atmosphere below one atmosphere in the processing chambers and the bridging chamber.

13. The system of claim 10, wherein the input set of the processing chambers, the bridging chamber, and the output set of the processing chambers form a first processing circuit, and further comprising an additional input set of the processing chambers, an additional bridging chamber, an additional output set of the processing chambers, and a transition chamber that are configured to be fluidly coupled with each other to form a second processing circuit.

14. The system of claim 13, wherein the transition chamber is configured to be fluidly coupled with one or more of the processing chambers in the output set of the first processing circuit to receive the device and to move the device to the additional input set of the processing chambers, the additional input set of the processing chambers configured to process and move the device in an additional input direction to the additional bridging chamber, the additional bridging chamber is configured to move the device in an additional transfer direction to one or more of the processing chambers of the additional output set, and the processing chambers of the additional output set configured to process and move the device in an additional output direction.

15. The system of claim 14, wherein the first processing circuit is disposed above the second processing circuit or the first processing circuit is disposed below the second processing circuit, and the transition chamber is configured to lift or lower the device between the first processing circuit and the second processing circuit.

16. The system of claim 13, wherein the processing chambers in the first processing circuit are configured to maintain at least one of a first temperature or a first pressure inside the processing chambers of the first processing circuit for processing the device and the processing chambers in the second processing circuit are configured to maintain at least one of a different, second temperature or a different, second pressure inside the processing chambers of the second processing circuit for processing the device.

17. A system comprising:
a first processing circuit having a first input set of processing chambers configured to be fluidly coupled and linearly aligned with each other along a first input direction, a first output set of the processing chambers configured to be fluidly coupled and linearly aligned with each other along a first output direction, and a first bridging chamber extending between the first input set of processing chambers and the first output set of processing chambers;
a second processing circuit having a second input set of processing chambers configured to be fluidly coupled and linearly aligned with each other along a second input direction, a second output set of the processing chambers configured to be fluidly coupled and linearly aligned with each other along a second output direction, and a second bridging chamber extending between the second input set of processing chambers and the second output set of processing chambers; and
a transition chamber configured to be fluidly coupled with the first processing circuit and the second processing circuit, wherein the first processing circuit is configured to process and move a semiconductor-based device through the processing chambers of the first processing circuit along the first input direction, the first transfer direction, and the first output direction, the transition chamber is configured to move the device to the second processing circuit, and the second processing circuit is configured to process and move the device through the processing chambers of the second processing circuit along the second input direction, the second transfer direction, and the second output direction to deposit one or more semiconductor layers on the device.

18. The system of claim 17, wherein the processing chambers are arranged in groups with the processing chambers in each group configured to deposit one or more sublayers of semiconductor material to form one or more semiconductor junctions on the device.

19. The system of claim 17, wherein the first input direction and the first output direction are oriented in opposite directions or the second input direction and the second output direction are oriented in opposite directions.

20. The system of claim 17, wherein the first transfer direction is perpendicular to at least one of the first input direction or the first output direction, or the second transfer direction is perpendicular to at least one of the second input direction or the second output direction.

21. The system of claim 17, wherein the first bridging chamber and the second bridging chamber are configured to be fluidly coupled with the processing chambers of the first processing circuit and the second processing circuit, respectively, to maintain at least one of an elevated temperature or a reduced pressure atmosphere below one atmosphere in the first processing circuit and the second processing circuit.

22. The system of claim 17, wherein the processing chambers of the first processing circuit are configured to maintain a first temperature for processing the device and the processing chambers of the second processing circuit are configured to maintain a different, second temperature for processing the device.

23. The system of claim 17, wherein the transition chamber is configured to receive the device and a first carrier from the processing chambers in the first processing circuit, separate the device from the first carrier, move the device to a second carrier in the second processing circuit, and move the device and the second carrier into the processing chambers of the second processing circuit.

24. The system of claim 23, wherein the transition chamber is configured to move the first carrier to one or more of the processing chambers in the first input set of the first processing chambers to that another device is placed onto a different, second carrier for being carried through the processing chambers of the first processing circuit.

25. The system of claim 23, wherein the transition chamber is configured to receive the second carrier from the processing chambers of the second processing circuit and place another device onto the second carrier for being carried through the processing chambers of the second processing circuit.

26. A multi-chamber system comprising:
a plurality of chambers linearly aligned with each other, wherein each chamber performs a different processing function or step in a manufacturing process of a photovoltaic module.

27. The system of claim 26, further comprising a conveyor subsystem that linearly moves the photovoltaic module between the chambers.

28. The system of claim 26, wherein a first chamber deposits a conductive lower electrode of the photovoltaic module, a different, second chamber deposits a semiconductor layer, and a different, third chamber deposits a conductive upper electrode of the photovoltaic module.
